(19) United States
(12) Patent Application Publication
(10) Pub. No.: US 2006/0183280 A1
(43) Pub. Date: Aug. 17, 2006

(54) Metal-insulator-metal capacitors and methods of forming the same

(75) Inventors: Sang-Jin Lee, Seoul (KR); Young-Joon Moon, Seoul (KR); Seung-Koo Lee, Suwon-si (KR); Kyung-Tae Lee, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/352,660

(22) Filed: Feb. 13, 2006

(30) Foreign Application Priority Data
Feb. 15, 2005 (KR) 10-2005-0012436

(51) Int. Cl. H01L 21/8242

(52) U.S. Cl. 438/239

(57) ABSTRACT

There are provided metal-insulator-metal (MIM) capacitors and methods of forming the same. The capacitors and the formation methods thereof provide a way of simplifying semiconductor fabrication processes, using component elements of the capacitor and insulating layers around the capacitor. To this end, lower and upper electrodes are sequentially stacked on a semiconductor substrate. A dielectric layer pattern is interposed between the upper and lower electrodes. An etch stop layer pattern and an etch buffer layer are disposed on the upper electrode and under the lower electrode, respectively. The upper and lower electrodes are disposed to expose the dielectric layer pattern and the etch buffer layer.

### CROSS-REFERENCE TO RELATED APPLICATION

This patent application claims priority from Korean Patent Application No. 10-2005-0012436, filed Feb. 15, 2005, the contents of which are hereby incorporated by reference in their entirety.

### BACKGROUND OF INVENTION

1. Technical Field

The present invention relates to discrete elements of a semiconductor device, and more particularly, to metal-insulator-metal (MIM) capacitors and methods of forming the same.

2. Discussion of the Related Art

Recently, semiconductor devices have been fabricated to include system-on-chip (SOC) type systems. The SOC has various kinds of semiconductor circuits on a semiconductor substrate. The semiconductor circuits have different functions for data transferring, caching, or the like. Typically, the SOC includes a metal-insulator-metal (MIM) capacitor. The MIM capacitor has higher efficiency in the SOC as compared with a metal-oxide-semiconductor (MOS) capacitor because the MIM capacitor is disposed at an upper portion of the semiconductor substrate. Thus, the use of the MIM capacitor allows the SOC to have sufficient space on the semiconductor substrate in order to comply with a design rule.

The MIM capacitor is formed by sequentially stacking upper and lower electrodes, a dielectric layer pattern between the electrodes, and electrical nodes of the capacitor on a semiconductor substrate. The electrical nodes of the MIM capacitor are disposed to contact the upper and lower electrodes through the semiconductor fabrication processes. The electrical nodes of the MIM capacitor are formed along with circuit interconnections of peripheral regions. Thus, process environments in the semiconductor fabrication processes may be unstable due to the characteristics of the upper and lower electrodes, the dielectric layer pattern, and the layers surrounding the circuit interconnections. This may degrade electrical characteristics of the MIM capacitor.

In one approach to these familiar problems, U.S. Pat. No. 6,740,974 to Takashi Yoshitomi (the '974 patent), which is incorporated herein by reference, discloses a semiconductor device having capacitors provided with a protective insulator film. According to the '974 patent, the semiconductor device includes a capacitor disposed on a diffusion-preventing film. The capacitor includes upper and lower electrodes, and a capacitive dielectric film between the electrodes. The protective insulator film is interposed between the capacitive dielectric film and the upper electrode. The protective insulator film may be disposed on the upper electrode. The diffusion-preventing film is silicon nitride (SiN). The protective insulator film is aluminum oxide (Al₂O₃).

The semiconductor device further includes an interlayer insulating film covering the capacitor. Via holes and wiring trenches penetrate the interlayer insulating film and are disposed on the upper and lower electrodes. The wiring trenches are disposed on the via holes. The via holes and the wiring trenches are filled with metal wirings. Before the metal wirings are formed, an annealing process using hydrogen is performed on the semiconductor device. The protective insulator film prevents hydrogen from penetrating into the capacitive dielectric film during the annealing process. The capacitive dielectric film is typically tantalum oxide (Ta₂O₅).

However, the capacitor of the conventional semiconductor device has a complicated structure. This is because the capacitor has the protective insulator film in addition to the capacitive dielectric film between the upper and lower electrodes. Further, the via holes are also formed in the peripheral regions of the capacitor as well as the upper and lower electrodes. The via holes penetrate the capacitor and its upper oxide material, and oxide and nitride materials in the peripheral regions concurrently. Thus, the via holes are disposed in the semiconductor device through two or more etch processes. One of the etch processes exposes the upper and lower electrodes and the nitride material in the peripheral region through the via holes. The remaining etch process(es) etch(es) the nitride material in the peripheral region through the via holes, using the lower and upper electrodes of the capacitor as etch buffer layers. Thus, the etch processes may damage the upper and lower electrodes at least two times during the etch processes.

### SUMMARY OF THE INVENTION

Therefore, according to some embodiments of the present invention, there are provided metal-insulator-metal (MIM) capacitors including an etch stop layer pattern and an etch buffer layer disposed on an upper electrode and below a lower electrode, respectively, and a dielectric layer pattern interposed between the electrodes. The capacitors are suitable for simplifying semiconductor fabrication processes.

According to some embodiments of the present invention, there are provided methods of forming MIM capacitors capable of simplifying semiconductor fabrication processes by using a dielectric layer pattern interposed between upper and lower electrodes, and an etch stop layer pattern and an etch buffer layer disposed on and below the dielectric layer pattern, respectively.

In accordance with an exemplary embodiment, the present invention provides a MIM capacitor and a method of forming the same.

According to an aspect of the present invention, the MIM capacitor includes lower and upper electrodes sequentially stacked on a semiconductor substrate. A dielectric layer pattern is interposed between the upper and lower electrodes. An etch stop layer pattern and an etch buffer layer are respectively disposed on the upper electrode and under the lower electrode. The upper and lower electrodes are disposed to expose portions of the dielectric layer pattern and the etch buffer layer. Thicknesses of center portions of the dielectric layer pattern and the etch buffer layer are different from thicknesses of other portions of the dielectric layer pattern and the etch buffer layer. The thicknesses of the other portions of the dielectric layer pattern and the etch buffer layer are the same as or less than a thickness of a center portion of the etch stop layer pattern.

According to another aspect of the present invention, a method of forming a MIM capacitor includes sequentially forming an etch buffer layer, a lower electrode layer, a dielectric layer, an upper electrode layer, and an etch stop layer on a semiconductor substrate. An upper electrode and an etch stop layer pattern are sequentially formed on the dielectric layer, using the etch stop layer and the upper electrode layer. A first cleaning process is performed after the formation of the etch stop layer pattern and the upper electrode. A lower electrode and a dielectric layer pattern are sequentially formed on the etch buffer layer, using the dielectric layer and the lower electrode layer. The upper and lower electrodes are formed to expose portions of the dielectric layer pattern and the etch buffer layer, respectively. A second cleaning process is performed after the formation of the dielectric layer pattern and the lower electrode. Thicknesses of center portions of the dielectric layer pattern and the etch buffer layer are formed to be different from thicknesses of other portions of the dielectric layer pattern and the etch buffer layer, respectively. Thicknesses of the other portions of the dielectric layer pattern and the etch buffer layer are formed to be less than or equal to a thickness of a center portion of the etch stop layer pattern.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a layout view showing a capacitor according to an embodiment of the present invention.

FIG. 2 is a cross-sectional view showing a capacitor taken along line I-I′ of FIG. 1.

FIGS. 3 to 10 are cross-sectional views illustrating a method of forming a capacitor according to an embodiment of the invention, taken along line I-I′ of FIG. 1.

### DETAILED DESCRIPTION OF THE INVENTION

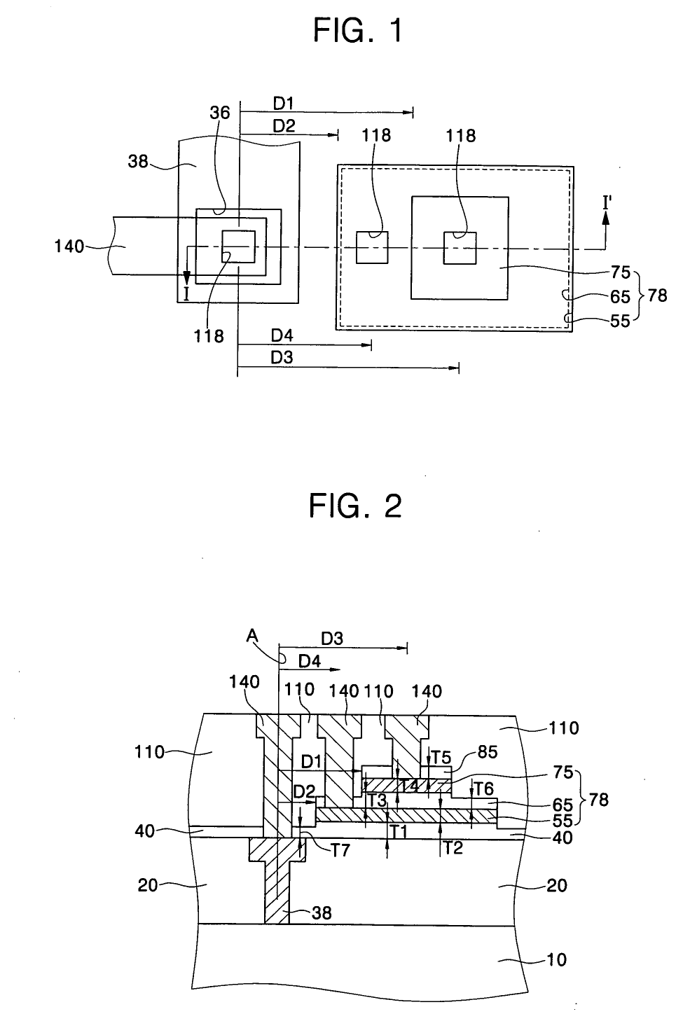

FIG. 1 is a layout view showing a capacitor according to the present invention, and FIG. 2 is a cross-sectional view showing a capacitor taken along line I-I′ of FIG. 1.

Referring to FIGS. 1 and 2, an etch buffer layer 40 is disposed on a semiconductor substrate 10. The etch buffer layer 40 has a convex surface on a predetermined region thereof, meaning that the etch buffer layer has a protrusion or higher thickness region. Upper and lower electrodes 75, 55 are sequentially stacked on the convex surface of the predetermined region of the etch buffer layer 40. The upper electrode 75 has a different area than the lower electrode 55. The lower electrode 55 is preferably disposed with an area greater than that of the upper electrode 75. Thus, the lower electrode 55 is disposed to expose a portion of the etch buffer layer 40. A thickness T7 of one portion of the etch buffer layer 40 is different from a thickness T1 of a center portion of the etch buffer layer 40. The thickness T7 of the portion of the etch buffer layer 40 is preferably smaller than the thickness T1 of the center portion of the etch buffer layer 40.

A thickness T4 of the upper electrode 75 is the same as a thickness T2 of the lower electrode 55. Alternatively, the thickness T4 of the upper electrode 75 and the thickness T2 of the lower electrode 55 may be different. The upper and lower electrodes 75, 55 are preferably metal nitride including titanium nitride (TiN) or tantalum nitride (TaN). The etch buffer layer 40 is preferably made of silicon nitride (Si₃N₄), silicon carbide (SiC), or silicon carbon nitride (SiCN).

A dielectric layer pattern 65 is interposed between the upper and lower electrodes 75, 55. The dielectric layer pattern 65 protrudes from the upper electrode 75, and has the same area as the lower electrode 55. The upper electrode 75 is disposed to expose a portion of the dielectric layer pattern 65. A thickness T6 of one portion of the dielectric layer pattern 65 is formed different from a thickness T3 of a center portion of the dielectric layer pattern 65. The thickness T6 is preferably smaller than the thickness T3 of the center portion of the dielectric layer pattern 65. An etch stop layer pattern 85 is disposed on the upper electrode 75. The etch stop layer pattern 85 has the same area as the upper electrode 75. The etch stop layer pattern 85 and the dielectric layer pattern 65 are preferably an insulating layer having the same etching ratio as that of the etch stop layer 40. Thicknesses T6, T7 of the portions of the dielectric layer pattern 65 and the etch buffer layer 40 are preferably less than or equal to a thickness T5 of a center portion of the etch stop layer pattern 85. Thus, the lower and upper electrodes 55, 75, and the dielectric layer pattern 65 interposed between the electrodes 55, 75 constitute one metal-insulator-metal (MIM) capacitor 78. The dielectric layer pattern 65 and the etch stop layer pattern 85 are preferably made of silicon nitride (Si₃N₄), silicon carbide (SiC), or silicon carbon nitride (SiCN).

A planarized interlayer insulating layer 20 is interposed between the semiconductor substrate 10 and the etch buffer layer 40. A lower plug interconnection 38 is disposed to be isolated by the planarized interlayer insulating layer 20. The lower plug interconnection 38 contacts the semiconductor substrate 10. Another plug interconnection (not shown) may be disposed between the semiconductor substrate 10 and the lower plug interconnection 38. The planarized interlayer insulating layer 20 is preferably formed of silicon oxide (SiO₂). The lower plug interconnection 38 is formed by sequentially stacking copper (Cu) and barrier metal including titanium nitride (TiN).

A protecting interlayer insulating layer 110 is formed to cover the etch buffer layer 40, the lower electrode 55, the dielectric layer pattern 65, the upper electrode 75, and the etch stop layer pattern 85. Upper plug interconnections 140 are disposed to be isolated by the protecting interlayer insulating layer 110, and disposed in the etch buffer layer 40, the dielectric layer pattern 65, and the etch stop layer pattern 85. The upper plug interconnection 140 in the etch buffer layer 40 is disposed on the lower plug interconnection 38 and contacts the lower plug interconnection 38. The protecting interlayer insulating layer 110 is preferably an insulating layer having the same etching ratio as that of the planarized interlayer insulating layer 20. The upper plug interconnection 140 is formed by sequentially stacking copper (Cu) and barrier metal including titanium nitride (TiN).

The upper electrode 75 and the etch stop layer pattern 85 are spaced away from a vertical line A passing through the center of the lower plug interconnection 38 or the upper plug interconnection 140 as much as a first distance D1. The lower electrode 55 and the dielectric layer pattern 65 are spaced away from the vertical line A passing through the center of the lower plug interconnection 38 or the upper plug interconnection 140 as much as a second distance D2. A center of the upper plug interconnection 140 in the etch stop layer pattern 85 is spaced away from the vertical line A passing through the center of the lower plug interconnection 38 or the upper plug interconnection 140 as much as a third distance D3. Further, a center of the upper plug interconnection 140 in the dielectric layer pattern 65 is spaced away from the vertical line A passing through the center of the lower plug interconnection 38 or the upper plug interconnection 140 as much as a fourth distance D4.

Hereinafter, methods of forming MIM capacitors according to the present invention will be described in detail.

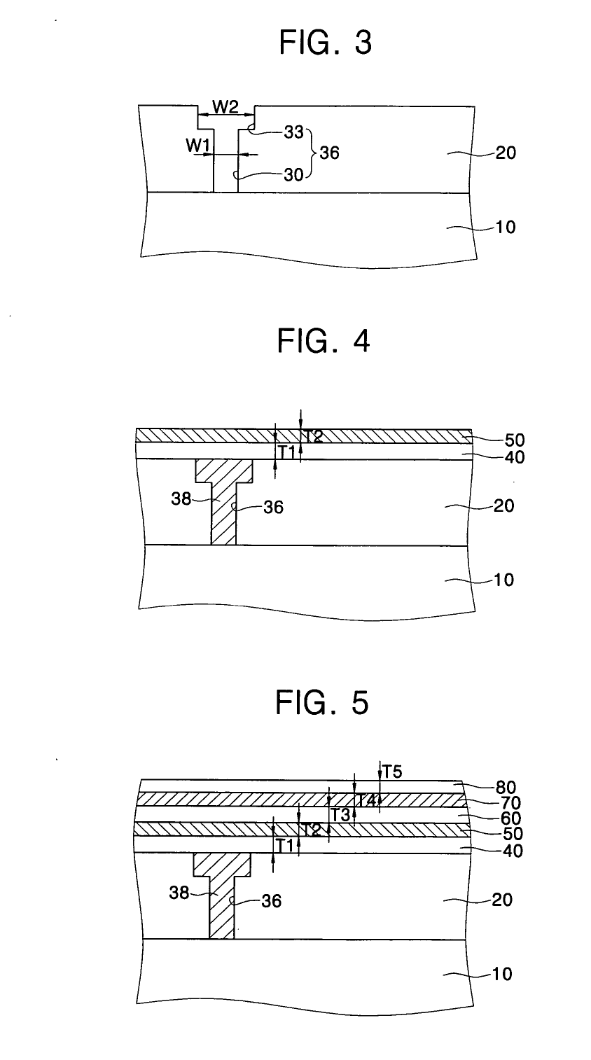

FIGS. 3 to 10 are cross-sectional views illustrating a method of forming a capacitor taken along line I-I′ of FIG. 1.

Referring to FIGS. 1, 3, and 4, a planarized interlayer insulating layer 20 is formed on a semiconductor substrate 10. A lower via hole 36 is formed in the planarized interlayer insulating layer 20. The lower via hole 36 may be formed to expose the semiconductor substrate 10. The lower via hole 36 is formed to have a lower contact hole 30 and a lower trench hole 33 on the contact hole 30. The lower contact hole 30 has a predetermined diameter W1. The lower trench hole 33 has a predetermined diameter W2. The planarized interlayer insulating layer is preferably formed of silicon oxide (SiO₂).

A lower plug interconnection 38 is formed to fill the lower via hole 36. An etch buffer layer 40 and a lower electrode layer 50 are sequentially formed on the planarized interlayer insulating layer 20 to cover the lower plug interconnection 38. The lower electrode layer 50 is formed with a predetermined thickness T2. The lower electrode layer 50 is preferably formed using metal nitride including titanium nitride (TiN), or tantalum nitride (TaN). The etch buffer layer 40 is formed with a predetermined thickness T1. The etch buffer layer 40 is preferably formed using a material selected from the group consisting of silicon nitride (Si₃N₄), silicon carbide (SiC), and silicon carbon nitride (SiCN). Another plug interconnection (not shown) may be formed between the semiconductor substrate 10 and the lower plug interconnection 38. The lower plug interconnection 38 is preferably formed by sequentially stacking copper (Cu) and barrier metal including titanium nitride (TiN).

Referring to FIGS. 1 and 5, a dielectric layer 60 is formed on the lower electrode layer 50. An upper electrode 70 and an etch stop layer 80 are sequentially formed on the dielectric layer 60. The etch stop layer 80 is formed with a predetermined thickness T5. The upper electrode layer 70 is formed with a predetermined thickness T4. The dielectric layer 60 is formed with a predetermined thickness T3. A thickness of the lower electrode layer 50 may be the same as a thickness of the upper electrode layer 70. The dielectric layer 60 and the etch stop layer 80 are preferably formed using a material selected from the group consisting of silicon nitride (Si₃N₄), silicon carbide (SiC), and silicon carbon nitride (SiCN). The upper electrode layer 70 is preferably formed using metal nitride including titanium nitride (TiN) or tantalum nitride (TaN).

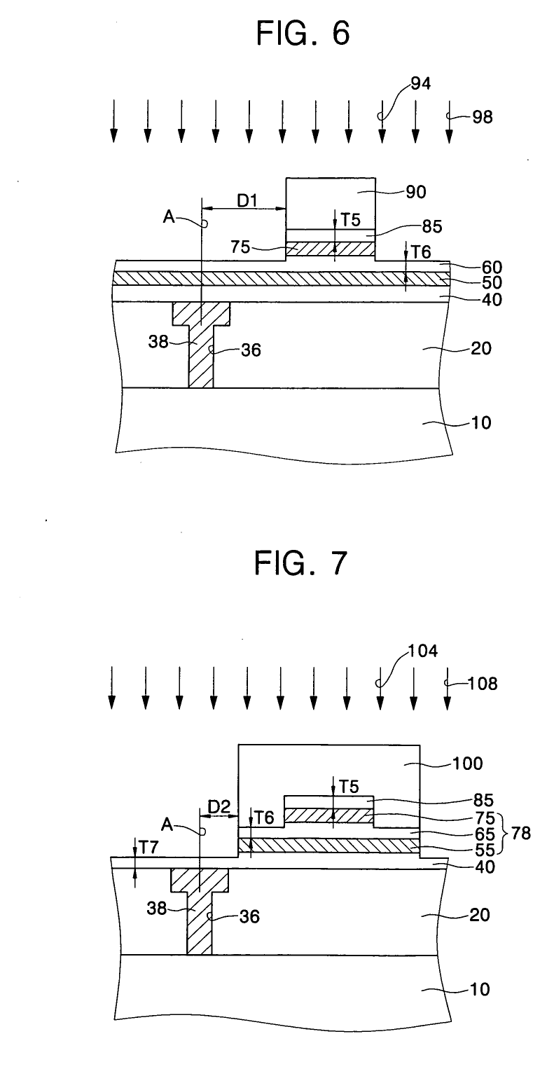

Referring to FIGS. 1 and 6, a photoresist pattern 90 is formed on the etch stop layer 80. An etch process 94 is performed on the etch stop layer 80 and the upper electrode layer 70 sequentially, using the photoresist pattern 90 as an etch mask. The etch process 94 forms an upper electrode 75 and an etch stop layer pattern 85 sequentially stacked on the dielectric layer 60. The etch stop layer pattern 85 and the upper electrode 75 are formed to have the same area. The etch process 94 is performed to partially remove the dielectric layer 60 on the etch buffer layer 40. At this time, the etch stop layer pattern 85 and the upper electrode 75 are spaced away from a vertical line A passing through the center of the lower plug interconnection 38 as much as a first distance D1. The upper electrode 75 is formed to expose a portion of the dielectric layer 60. A thickness T6 of the portion of the dielectric layer 60 is different from the thickness T3 of a center portion of the dielectric layer 60.

After the etch process 94, the photoresist pattern 90 is removed from the semiconductor substrate 10. A first cleaning process 98 is performed on the semiconductor substrate having the etch stop layer pattern 85 and the upper electrode 75. The first cleaning process 98 is performed to remove a polymer layer created due to the etch process 94, and damaged portions of sidewalls of the upper electrode 75 and the etch stop layer pattern 85 due to the etch process 94. The first cleaning process 98 is preferably performed using an etchant including hydrofluoric acid (HF). The first cleaning process 98 may be performed using an ashing technique.

After the first cleaning process 98 is performed, the thickness T6 of the portion of the dielectric layer 60 is preferably formed the same as or less than the thickness T5 of a center portion of the etch stop layer pattern 85.

Referring to FIGS. 1 and 7, a photoresist pattern 100 is formed on the dielectric layer 60 to cover the etch stop layer pattern 85 and the upper electrode 75. The photoresist pattern 100 is formed to expose the dielectric layer 60. The photoresist pattern 100 is formed to have an area larger than that of the photoresist pattern 90 of FIG. 6. An etch process 104 is sequentially performed on the dielectric layer 60, the lower electrode layer 50, and the etch buffer layer 40, using the photoresist pattern 100 as an etch mask.

The etch process 104 forms a lower electrode 55 and a dielectric layer pattern 65 sequentially stacked on the etch buffer layer 40. The etch process 104 is performed to partially remove the etch buffer layer 40 on the semiconductor substrate 10. The dielectric layer pattern 65 and the lower electrode 55 are formed to have the same area. The lower electrode 55 and the dielectric layer pattern 65 are spaced away from the vertical line A passing through the center of the lower plug interconnection 38 as much as a second distance D2. The lower electrode 55 is formed to expose a portion of the etch buffer layer 40. A thickness T7 of the portion of the etch buffer layer 40 is formed different from the thickness T1 of a center portion of the etch buffer layer 40.

After the performance of the etch process 104, the photoresist pattern 100 is removed from the semiconductor substrate 10. A second cleaning process 108 is performed on the semiconductor substrate having the dielectric layer pattern 65 and the lower electrode 55. The second cleaning process 108 is performed to remove a polymer layer created due to the etch process 104, and damaged portions of sidewalls of the dielectric layer pattern 65 and the lower electrode 55 due to the etch process 104. The second cleaning process 108 is preferably performed using an etchant including hydrofluoric acid (Hf). The second cleaning process 108 may be performed using an ashing technique.

After the second cleaning process 108 is performed, thicknesses T6, T7 of the portions of the dielectric layer pattern 65 and the etch buffer layer 40 are preferably formed to be less than or equal to the thickness T5 of the center portion of the etch buffer layer 85. Thus, the lower electrode 55, the dielectric layer pattern 65, and the upper electrode 75 form one MIM capacitor 78 on the semiconductor substrate 10. The MIM capacitor 78 is formed to have a relatively simple structure as compared with a conventional structure, for example, a MOS capacitor.

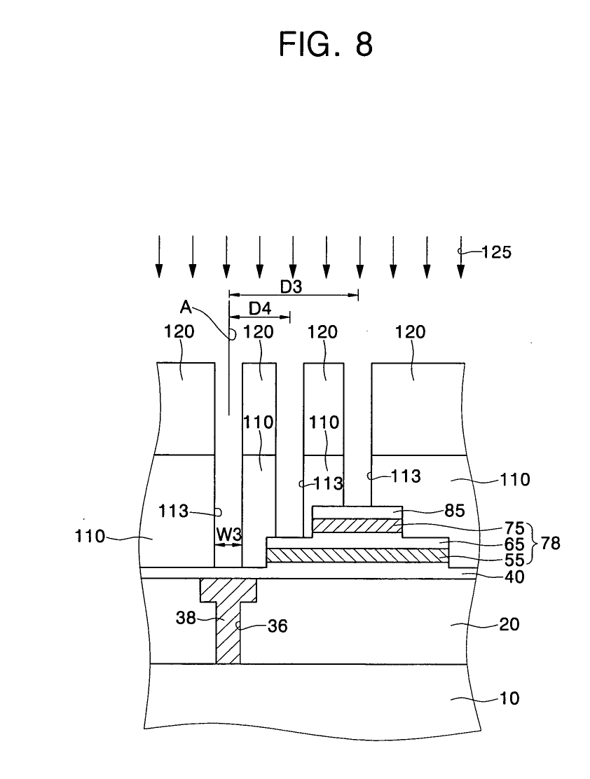

Referring to FIGS. 1 and 8, a protecting interlayer insulating layer 110 is formed on the semiconductor substrate 10 to sufficiently cover the etch buffer layer 40, the lower electrode 55, the dielectric layer pattern 65, the upper electrode 75, and the etch stop layer pattern 85. A photoresist layer 120 is formed on the protecting interlayer insulating layer 110. The photoresist layer 120 has openings. The openings of the photoresist layer 120 are preferably formed to be disposed above portions of the etch buffer layer 40, the dielectric layer pattern 65, and the etch stop layer pattern 85. The protecting interlayer insulating layer 110 is preferably formed using an insulating layer having the same etching ratio as that of the planarized interlayer insulating layer 20.

An etch process 125 is performed on the protecting interlayer insulating layer 110 through the openings, using the photoresist layer 120 as an etch mask. The etch process 125 forms upper contact holes 113 in the protecting interlayer insulating layer 110. The upper contact holes 113 are formed to expose the etch buffer layer 40, the dielectric layer pattern 65, and the etch stop layer pattern 85. Each of the upper contact holes 113 is formed to have a predetermined width W3. The upper contact hole 113 exposing the etch buffer layer 40 is formed to be disposed on the lower via hole 36. A center of the upper contact hole 113 exposing the etch stop layer pattern 85 is spaced away from the vertical line A passing through a center of the upper contact hole 113 exposing the etch buffer layer 40 over the lower plug interconnection 38 as much as a third distance D3. A center of the upper contact hole 113 exposing the dielectric layer pattern 65 is spaced away from a vertical line A passing through the center of the upper contact hole 113 exposing the etch buffer layer 40 over the lower plug interconnection 38 as much as a fourth distance D4.

After the etch process 125 is performed, the photoresist layer 120 is removed from the semiconductor substrate 10.

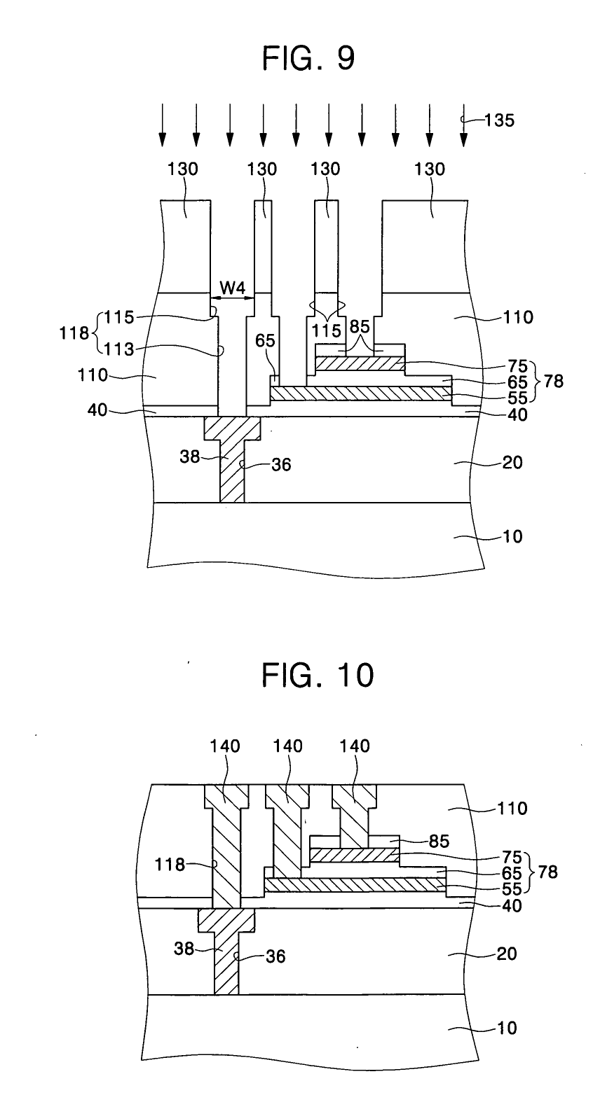

Referring to FIGS. 1 and 9, a photoresist layer 130 is formed on the semiconductor substrate having the upper contact holes 113. The photoresist layer 130 is formed to have openings. Each of the openings of the photoresist layer 130 is formed to have a width greater than the width W3 of each of the openings of the photoresist layer 120 of FIG. 8. Further, the openings of the photoresist layer 130 are formed on the upper contact holes 113 respectively.

An etch process 135 is performed on the protecting interlayer insulating layer 110 through the openings, using the photoresist layer 130 as an etch mask. The etch process 135 is performed to partially remove the protecting interlayer insulating layer 110. Further, the etch process 135 removes the exposed portion of the etch buffer layer 40, the exposed portion of the dielectric layer pattern 65, and the exposed portion of the etch stop layer pattern 85, thereby exposing the lower plug interconnection 38, the lower electrode 55, and the upper electrode 75. Thus, the etch process 135 forms upper trench holes 115 on the upper contact holes 113 respectively.

Each of the upper trench holes 115 and upper contact holes 113 form one upper via hole 118. Each of the upper trench holes 115 is formed to have a predetermined width W4 different from the width W3 of each of the upper contact holes 113. The predetermined width W4 of the upper trench holes 115 is formed to have a size greater than the predetermined width W3 of the upper contact holes 113 of FIG. 8. After the performance of the etch process 125, the photoresist layer 130 is removed from the semiconductor substrate 10.

According to the present invention, the etch processes 125, 135 of FIGS. 8 and 9 can be performed on the overall surface of the semiconductor substrate 10 under stable etch conditions as compared to a conventional method. This is because the etch processes 125, 135 etch the protecting interlayer insulating layer 110 with a same etch rate during the formation of the upper contact holes 113 and the upper trench holes 115. Thus, the etch processes 125, 135 can minimize physical damage to the lower and upper electrodes 55, 75 during the etch processes. Further, the MIM capacitor 78 having the lower electrode 55, the dielectric layer pattern 65, and the upper electrode 75 is formed by a more simplified deposition process than that performed in the conventional method. Thus, the simplification of the etch conditions and the deposition process leads to increase in productivity of the MIM capacitor 78.

Referring to FIGS. 1 and 10, upper plug interconnections 140 are formed to fill the upper via holes 118 respectively. The upper plug interconnections 140 contact the lower plug interconnection 38, the lower electrode 55, and the upper electrode 75 respectively. The upper plug interconnections 140 of the lower and upper electrodes 55, 75 are electrical nodes of the MIM capacitor 78 respectively. The upper plug interconnections 140 are preferably formed by sequentially stacking copper (Cu) and barrier metal including titanium nitride (TiN).

As described above, the present invention provides an approach to increasing productivity of semiconductor devices in the semiconductor fabrication line by simplifying the structures of a MIM capacitor and component elements around the MIM capacitor. Therefore, the present invention minimizes physical damage to the capacitor by stably maintaining the etch conditions of etch processes on the MIM capacitor.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A metal-insulator-metal (MIM) capacitor comprising:
lower and upper electrodes sequentially stacked on a semiconductor substrate;
a dielectric layer pattern interposed between the upper and lower electrodes; and
an etch stop layer pattern and an etch buffer layer disposed on the upper electrode and under the lower electrode, respectively, wherein
the upper and lower electrodes are disposed to expose portions of the dielectric layer pattern and the etch buffer layer, and thicknesses of center portions of the dielectric layer pattern and the etch buffer layer are different from thicknesses of other portions of the dielectric layer pattern and the etch buffer layer, respectively, and thicknesses of the other portions of the dielectric layer pattern and the etch buffer layer are less than or equal to a thickness of a center portion of the etch stop layer pattern.

2. The MIM capacitor according to claim 1, wherein the upper and lower electrodes have different areas.

3. The MIM capacitor according to claim 1, wherein areas of the upper and lower electrodes are substantially the same as those of the etch stop layer pattern and the dielectric layer pattern, respectively.

4. The MIM capacitor according to claim 1, wherein the upper and lower electrodes have substantially the same thickness.

5. The MIM capacitor according to claim 1, wherein the upper and lower electrodes have different thicknesses.

6. The MIM capacitor according to claim 1, wherein the upper and lower electrodes comprise a metal nitride selected from the group consisting of titanium nitride (TiN) and tantalum nitride (TaN).

7. The MIM capacitor according to claim 1, wherein the etch buffer layer, the dielectric layer pattern, and the etch stop layer pattern comprise a material selected from the group consisting of silicon nitride (SiN), silicon carbide (SiC), and silicon carbon nitride (SiCN).

8. The MIM capacitor according to claim 1, further comprising:
a planarized interlayer insulating layer interposed between the semiconductor substrate and the etch buffer layer; and
a protecting interlayer insulating layer covering the etch buffer layer, the lower electrode, the dielectric layer pattern, the upper electrode, and the etch stop layer pattern.

9. The MIM capacitor according to claim 8, further comprising:
upper plug interconnections isolated by the protecting interlayer insulating layer, and disposed in the etch buffer layer, the dielectric layer pattern, and the etch stop layer pattern; and
a lower plug interconnection isolated by the planarized interlayer insulating layer, and disposed under the upper plug interconnection in the etch buffer layer.

10. A method of forming a MIM capacitor comprising:
sequentially forming an etch buffer layer, a lower electrode layer, a dielectric layer, an upper electrode layer, and an etch stop layer on a semiconductor substrate;
sequentially forming an upper electrode and an etch stop layer pattern on the dielectric layer, using the etch stop layer and the upper electrode layer;
performing a first cleaning process after forming the etch stop layer pattern and the upper electrode;
sequentially forming a lower electrode and a dielectric layer pattern on the etch buffer layer, using the dielectric layer and the lower electrode layer, the upper and lower electrodes being formed to expose portions of the dielectric layer pattern and the etch buffer layer, respectively; and
performing a second cleaning process after forming the dielectric layer pattern and the lower electrode, wherein
thicknesses of center portions of the dielectric layer pattern and the etch buffer layer are formed to be different from thicknesses of other portions of the dielectric layer pattern and the etch buffer layer, respectively, and thicknesses of the other portions of the dielectric layer pattern and the etch buffer layer are formed to be less than or equal to a thickness of a center portion of the etch stop layer pattern.

11. The method according to claim 10, wherein the first and second cleaning processes are performed using an etchant including hydrofluoric acid (Hf).

12. The method according to claim 10, wherein the first and second cleaning processes are performed using an ashing technique.

13. The method according to claim 10, wherein the formation of the etch stop layer pattern and the upper electrode comprises:
forming a photoresist pattern on the etch stop layer;
performing an etch process on the etch stop layer and the upper electrode layer sequentially, using the photoresist pattern as an etch mask; and
removing the photoresist pattern from the semiconductor substrate, wherein
the etch process is performed to partially remove the dielectric layer on the etch buffer layer, the photoresist pattern is formed to have a different area from that of each of the dielectric layer pattern and the lower electrode, and the etch stop layer pattern and the upper electrode have substantially the same area.

14. The method according to claim 13, further comprising:
forming a protecting interlayer insulating layer on the semiconductor substrate to sufficiently cover the etch buffer layer, the lower electrode, the dielectric layer pattern, the upper electrode, and the etch stop layer pattern;
forming upper via holes to penetrate the protecting interlayer insulating layer, and to be disposed in the etch buffer layer, the dielectric layer pattern, and the etch stop layer pattern; and
forming upper plug interconnections to fill the upper via holes, respectively, wherein
the photoresist pattern is spaced away from a vertical line passing through a center of the upper via hole in the etch buffer layer with a predetermined distance.

15. The method according to claim 10, wherein the formation of the etch buffer layer, the lower electrode, and the dielectric layer pattern comprises:
forming a photoresist pattern on the dielectric layer to cover the etch stop layer pattern and the upper electrode, the photoresist pattern being formed to expose the dielectric layer;
performing an etch process on the dielectric layer, the lower electrode layer, and the etch buffer layer sequentially, using the photoresist pattern as an etch mask; and
removing the photoresist pattern from the semiconductor substrate, wherein
the etch process is performed to partially remove the etch buffer layer on the semiconductor substrate, and the dielectric layer pattern and the lower electrode have substantially the same area.

16. The method according to claim 15, further comprising:
forming a planarized interlayer insulating layer between the semiconductor substrate and the etch buffer layer;
forming a lower via hole penetrating the planarized interlayer insulating layer and exposing the semiconductor substrate; and
forming a lower plug interconnection to fill the lower via hole, wherein the photoresist pattern is spaced away from a vertical line passing through a center of the lower via hole with a predetermined distance.

17. The method according to claim 10, wherein the upper and lower electrode layers are formed using metal nitride including at least one of titanium nitride (TiN) and tantalum nitride (TaN).

18. The method according to claim 10, wherein the upper and lower electrodes are formed to have substantially the same thickness.

19. The method according to claim 10, wherein the upper and lower electrodes are formed to have different thicknesses.

20. The method according to claim 10, wherein the etch buffer layer, the dielectric layer, and the etch stop layer are formed using a material selected from the group consicting of silicon nitride (SiN), silicon carbide (SiC), and silicon carbon nitride (SiCN).
